(19) United States
(12) Patent Application Publication
(10) Pub. No.: US 2010/0020837 A1
(43) Pub. Date: Jan. 28, 2010

(54) SEMICONDUCTOR LIGHT EMISSION DEVICE HAVING AN IMPROVED CURRENT CONFINEMENT STRUCTURE, AND METHOD FOR CONFINING CURRENT IN A SEMICONDUCTOR LIGHT EMISSION DEVICE

(75) Inventor: Kian-Paau Gan, Singapore (SG)

Correspondence Address: Kathy Manke;Avago Technologies Limited, 4380 Ziegler Road, Fort Collins, CO, 80525, US

(73) Assignee: Avago Technologies Fiber IP (Singapore) Pte. Ltd., Singapore (SG)

(21) Appl. No.: 12/177,223

(22) Filed: Jul. 22, 2008

(51) Int. Cl. H01S 5/30

(52) U.S. Cl. 372/45.013

(57) ABSTRACT

A semiconductor light emission device is provided that has a current confinement region that comprises a diffusion accommodation layer located adjacent the active region. The diffusion accommodation layer comprises a material that has a higher bandgap than the bandgap of the material in the active region. Diffusion of dopants into portions of the diffusion accommodation layer forms p+/n junctions on each side of the p/n junction that exists in the active region. The material of the diffusion accommodation layer has a bandgap that is higher than the bandgap of the material of the active region, which ensures that the p+/n junctions turn on at a threshold voltage level that is higher than the threshold voltage level at which the p/n junction turns on. Because of this, the p+/n junctions are effectively turned off while the p/n junction is turned on, which causes the electrical current to be channeled away from the p+/n junctions and into the p/n junction, thereby confining the current to a particular area in the active region.

### TECHNICAL FIELD OF THE INVENTION

The invention relates to semiconductor light emission devices, such as, for example, light emitting diodes (LEDs) and lasers. More particularly, the invention relates to a semiconductor light emission device having an improved current confinement structure.

### BACKGROUND OF THE INVENTION

Semiconductor light emission devices, such as LEDs and lasers, for example, have an active light emission layer in which electrons and holes are converted into photons to produce optical emissions. FIG. 1 illustrates a cross-sectional view of a typical LED 2. The LED 2 has an n-type substrate 3 on which one or more other n-type layers 5 are epitaxially grown. On top of the n-type layers 5, one or more active layers are grown to form an active region 13 where holes and electrons combine to produce photons. On top of the active region 13, one or more p-type layers 7 are grown. A p-type electrical contact 9 is located on the uppermost layer of p-type layers 7. An n-type electrical contact 11 is located on the bottom surface of the substrate 3. When positive and negative electrodes (not shown) are connected to the p-type and n-type contacts 9 and 11, respectively, and a voltage is applied across the device 2 to forward bias the device 2, electrical current (holes and electrons) is injected into the active region 13, which is essentially a diode p/n junction. The holes move in a direction away from p contact 9 toward the n-type contact 11 and electrons move in a direction away from n-type contact 11 toward p contact 9. As the holes and electrons meet at the active region 13, the holes and electrons recombine to produce electromagnetic radiation, commonly referred to as electroluminescence, which is emitted from the device 2 as light.

When the positive voltage bias is removed, or a negative bias voltage is applied, the holes and electrons move in opposite directions away from the active 13 and toward the p-type and n-type contacts 9 and 11, respectively. In this case, the active region 13 becomes depleted of holes and electrons. In LEDs, the photons that are emitted from the device are not all in phase, and so the light that is emitted from the device is said to be non-coherent light. In laser diodes, mirrors are included in the device to cause some of the photons to be reflected within the active region 13 to produce a pumping action. This pumping action results in the photons that are emitted from the device being in phase. In this case, the light emitted from the device is said to be coherent light, i.e., laser light.

The semiconductor device 2 typically also includes a current confinement structure 15 that serves to channel the current to a limited area in the active region 13 where the electrical current will be converted into light. The use of a current confinement structure in semiconductor light emission devices can increase light conversion efficiency by channeling the current only to an area in the active region from which light can escape the device. This prevents current from being injected into an area in the active region where the resulting light produced in the active region might be blocked (e.g., by an opaque metal contact) and thereby prevented from escaping the device. Current confinement is also essential for applications that require high current density at the p/n junction, such as in high speed LED and laser diode device applications.

There are many existing current confinement techniques that are used in semiconductor light emission devices. In the device 2 shown in FIG. 1, the current confinement structure 15 is an etched mesa structure. The structure 15 is formed by performing either a wet chemical etching process that penetrates the active region 13 or a dry plasma etching process, which typically stops before the active region 13 has been penetrated in order to avoid potential plasma damage to the device. This technique, however, can result in the device having poor thermal performance due to material loss where the material was etched away to form the mesa structure. In addition, this technique results in the device having a non-planar shape, which complicates the manufacturing process and compromises device reliability.

Another technique for providing current confinement in semiconductor light emission devices involves selectively oxidizing portions of a buried semiconductor layer to confine the current. FIG. 2 illustrates a semiconductor light emission device 32 that is identical to the semiconductor light emission device 2 shown in FIG. 2, except that the device 32 does not include the mesa and instead includes portions 25 of layer 7 that have been selectively oxidized. The oxidized portions 25 do not conduct current, and thus cause the current to be channeled into selected portions of the active region 13. Because the lengths of the oxidized portions 25 can be made relatively large, and because material is not removed to form a mesa as in FIG. 2, the device 32 provides better thermal performance than the device 2 shown in FIG. 1. However, the technique has disadvantages in terms of increased processing complexity due to the non-planar shape of the device 32. In addition, the resulting devices produced by the process have limited reliability due the etching that must be performed to access the portions 25 of the buried layer 7 for oxidation.

FIG. 3 illustrates a semiconductor light emission device 42 that is identical to the semiconductor light emission device 2 shown in FIG. 2, except that the device 42 does not include the mesa and instead includes areas 45 where protons have been implanted in p-type layer 7. The areas 45 provide the current confinement structure of the device 42. Implanting protons in the areas 45 makes these areas semi-insulating, which ensures that holes will not pass through these areas, but will be channeled between them and into a particular area in the active region 13. This type of current confinement structure provides advantages in terms of ease of processing due to the planarity of the device 42, which facilitates manufacturing and improves device reliability. The areas 45 cannot be too near to the active region 13 due to concerns about implant damage, which means that some of the current will spread and leak outside of confined area. This limitation results in the confinement structure not being as effective as desired. Also, the areas 45 create light blockage issues due to the fact that the proton implantation renders the areas 45 semi-insulating, requiring that the metal p contact 9 be inside of the non-implanted emission window.

FIG. 4 illustrates a semiconductor light emission device 52 that is similar to the semiconductor light emission device 42 shown in FIG. 3, except that portions of layer 7 have been etched away, after which another layer of p+-type material 55 is epitaxially regrown. The result is that the portion of the regrown layer 55 that is over the etched portion of layer 7 is reverse biased while the portion of the regrown layer 55 that is over the unetched portion of layer 7 is forward biased. The reverse biased junction serves to block current so that current is confined only to the forward biased junction. Although this type of current confinement structure is effective, the manufacturing process has increased complexity due to the fact that the surface of layer 7 that is used for the regrowth of layer 55 needs to be absolutely clean. In addition, the non-planar shape of the device 52 results in further process complexity, as well as device reliability issues.

Accordingly, a need exists for a semiconductor light emission device having an improved current confinement structure as compared to existing current confinement structures and that provides better thermal performance and device reliability than that provided by existing current confinement structures.

### SUMMARY OF THE INVENTION

The invention provides a semiconductor light emission device comprising a substrate of n-type material, at least a first layer of n-type material disposed on an upper surface of the substrate, at least one diffusion accommodation layer of n-type material disposed on the first layer of n-type material, at least one active layer of material disposed on the diffusion accommodation layer to provide an active region in the semiconductor light emission device for conversion of electrons and holes into photons, at least one layer of p-type material disposed on the active layer, at least one p contact disposed on the first layer of p-type material, at least one n contact disposed on a bottom surface of the substrate, and at least first and second diffusion areas in which p dopants have been diffused into the semiconductor light emission device. The material of the diffusion accommodation layer has a bandgap that is higher than the bandgap of the material of the active layer. The first and second diffusion areas pass through the first layer of p-type material and the active region and terminate in the diffusion accommodation layer. First and second p+/n junctions exist in the diffusion accommodation layer where the first and second diffusion areas terminate in the diffusion accommodation layer. A p/n junction exists in the active region. The existence of the first and second p+/n junctions in the higher bandgap material of the diffusion accommodation layer operate as a current confinement structure by causing electrical current to be channeled away from the p+/n junctions and into the p/n junction.

The invention provides a method for performing current confinement in a semiconductor light emission device. The method comprises providing a semiconductor light emission device comprising at least an active region disposed between first and second layers, and forming first and second diffusion areas in the semiconductor device. The active region comprises at least one layer of p-n material. The first layer comprises at least one diffusion accommodation layer of n-type material. The second layer comprises at least one layer of p-type material. The first and second diffusion areas are formed by diffusing p dopants into the semiconductor light emission device such that the first and second diffusion areas pass through the first layer and the active region and terminate in the diffusion accommodation layer. The material of the diffusion accommodation layer has a bandgap that is higher than the bandgap of the material of the active layer. A first p+/n junction exists where the first diffusion area terminates in the diffusion accommodation layer. A second p+/n junction exists where the second diffusion area terminates in the diffusion accommodation layer. A p/n junction exists in the active region. The existence of the first and second p+/n junctions in the higher bandgap material of the diffusion accommodation layer operates as a current confinement structure by causing electrical current to be channeled away from the p+/n junction and into the p/n junction.

These and other features and advantages of the invention will become apparent from the following description, drawings and claims.

### BRIEF DESCRIPTION OF THE DRAWINGS

FIG. 1 illustrates a cross-sectional plan view of a known semiconductor light emission device that has an etched mesa current confinement structure.

FIG. 2 illustrates a cross-sectional plan view of a known semiconductor light emission device that has a current confinement structure formed by oxidizing portions of a buried p-type layer.

FIG. 3 illustrates a cross-sectional plan view of a known semiconductor light emission device that has a current confinement structure formed by implanting protons in selected areas in the p-type layer above the active region.

FIG. 4 illustrates a cross-sectional plan view of a known semiconductor light emission device that has a current confinement structure formed by etching through the n-type layer above the active region and regrowing the p-type layer.

FIGS. 5A-5D illustrate cross-sectional plan views of the semiconductor light emission device of the invention in accordance with an embodiment as the device undergoes processing steps.

### DETAILED DESCRIPTION OF AN EMBODIMENT

The invention provides a semiconductor light emission device having a current confinement region that comprises a diffusion accommodation layer located adjacent the active region. The diffusion accommodation layer comprises a material that has a higher bandgap than the bandgap of the material in the active region. Diffusion of dopants into portions of the diffusion accommodation layer causes p+/n junctions to exist in the diffusion accommodation layer on either side of the p/n junction that exists in the active region. Due to the material of the diffusion accommodation layer having a bandgap that is higher than the bandgap of the material of the active region, the p+/n junctions turn on at a threshold forward bias voltage level that is higher than the threshold forward bias voltage level at which the p/n junction turns on. Because of this, the p+/n junctions are effectively turned off while the p/n junction is turned on, which causes electrical current to be channeled away from the p+/n junctions and into the p/n junction, thereby confining the current to a particular area of the active region.

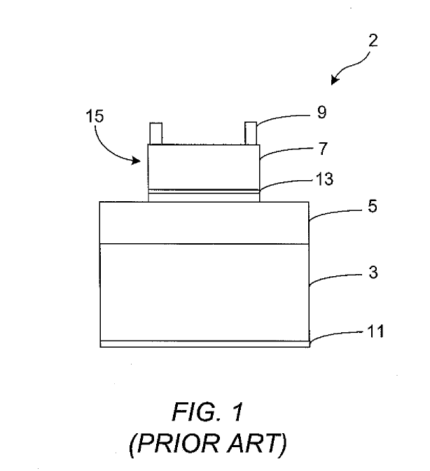

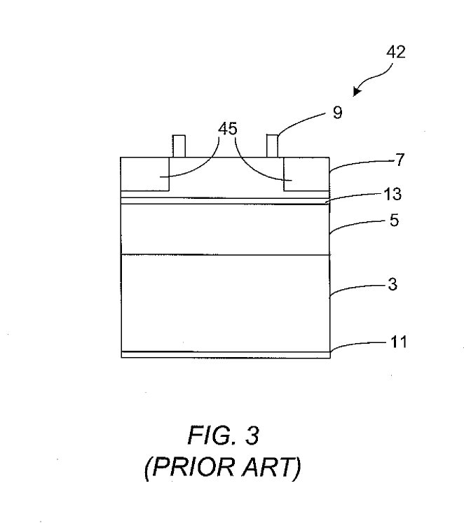

The current confinement method and structure used in accordance with the invention have several advantages over the known current confinement structures and methods described above with reference to FIGS. 1-4. For example, as indicated above, when using ion implantation, the implanted areas cannot be too near to the active region due to the danger of causing implant damage to the device. Consequently, the use of proton implantation to confine current (FIG. 3) results in the current being confined to a region that is above the active region, and thus some of the current will spread and leak outside of the confined area into the non-implanted region above the active region. In contrast, the current confinement structure of the invention confines current directly to the active region, resulting in a higher confinement factor. Also, with ion implantation, the p-contact metal generally must be located in the emission window due to the insulating effects of the implanted regions, which results in light blockage issues. In the semiconductor device of the invention, the p-type contact metal is not required to be placed inside of the optical emission window, which eliminates this particular light blockage issue.

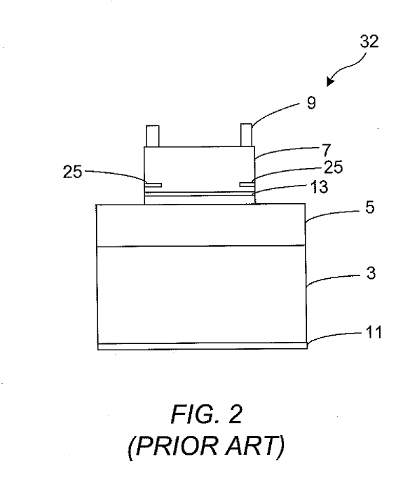

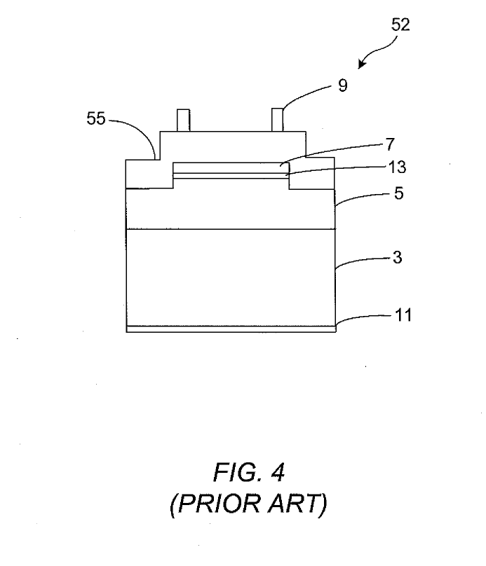

In contrast to the etched mesa (FIG. 1), selective oxidation (FIG. 2) and layer regrowth (FIG. 4) methods and structures, the invention uses dopant diffusion in conjunction with the diffusion accommodation layer to create the current confinement structure. This results in the semiconductor device of the invention having a planar shape, which provides improvements in terms of thermal performance, processing complexity and device reliability. Therefore, the disadvantages associated with the non-planar shapes described above with reference to FIGS. 1, 2 and 4 are avoided.

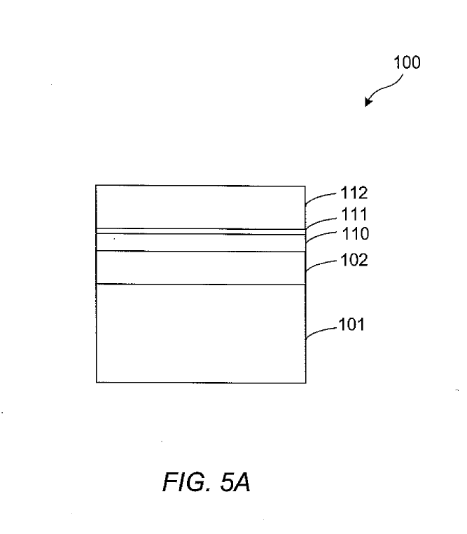

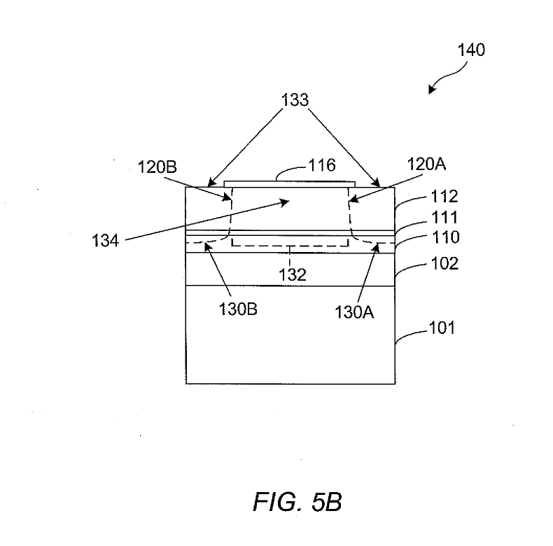

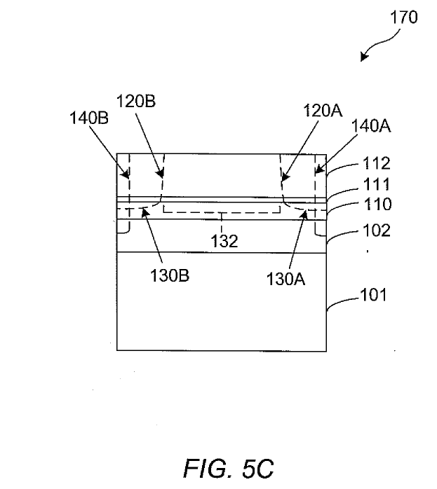

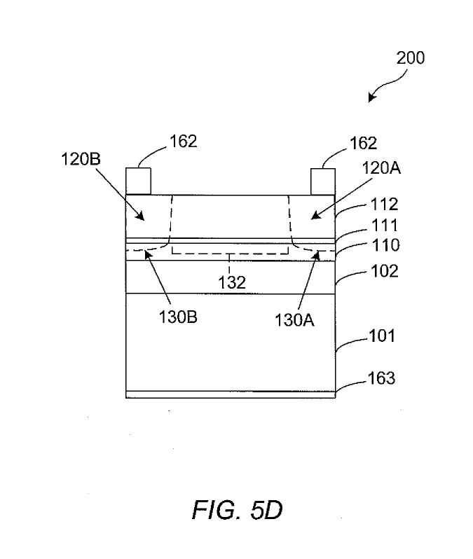

FIGS. 5A-5D illustrate cross-sectional plan views of the semiconductor light emission device of the invention in accordance with an embodiment as processing steps are performed to create the device. With reference to FIG. 5A, the process begins with an n-type wafer 101 as the starting material. At least one layer 102 of n-type material is epitaxially grown on the surface of the wafer 101. At least one diffusion accommodation layer 110 of n-type material is then grown on the layer 102. At least one active layer 111 of material that makes up the active region is then grown on the diffusion accommodation layer 110. The active layer 111 is typically made of a p-n material. At least one layer 112 of p-type material is then grown on the active layer 111. The result of these process steps is the device 100.

The term “n-type material”, as that term is used herein, means that the material has more negative carriers (electrons) than positive carriers (holes). The term “p-type material”, as that term is used herein, means that the material has more positive carriers (holes) than negative carriers (electrons). The term “p-n material”, as that term is used herein, means that the material has an equal number of holes and electrons such that it is neither positively nor negatively charged, but rather, is electrically at equilibrium.

The invention is not limited with respect to the materials that are used for the substrate 101 or for the layers 102, 110, 111, and 112. An example of a suitable materials system for the device 100 is the gallium arsenide/aluminum gallium arsenide (GaAs/AlGaAs) materials system. If this materials system is chosen for the device 100, the active layer 111 will typically be made of GaAs and the n-type diffusion accommodation layer 110 will typically be made of AlAs. Because GaAs has a bandgap of 1.42 electron-volts (eV) and AlAs has a bandgap of 2.17 eV, the diffusion accommodation layer 110 has a bandgap that is higher than the bandgap of the active layer 111, which is needed in order to provide a p+/n junction that has a threshold voltage that is higher than the threshold voltage of the p/n junction of the active layer 111. If this material system is used, the substrate 101 will typically be an n-type GaAs wafer, and the layers 102 and 112 will typically be made of n-type and p-type AlGaAs, respectively.

Another example of a suitable materials system for the device 100 is the gallium arsenide/aluminum indium gallium phosphide (GaAs/AlInGaP) materials system. If this system is chosen for the device 100, the active layer 111 will typically be made of InGaP and the diffusion accommodation layer 110 will typically be made of AlInP. Because AlInP has a bandgap of 2.35 eV and InGaP has a bandgap of 1.9 eV, the diffusion accommodation layer 110 has a bandgap that is higher than the bandgap of the active layer 111. If this material system is used, the substrate 101 will typically be an n-type GaAs wafer, and layers 102 and 112 will typically be made of n-type and p-type AlInGaP, respectively.

With reference to FIG. 5B, after the device 100 described above with reference to FIG. 5A has been created, the device 100 is placed in a reactor or ampoule (not shown) and a deep diffusion process is performed to produce the device 140 shown in FIG. 5B. Prior to performing the diffusion process, a diffusion barrier layer 116 is deposited and patterned to define diffusion apertures. An example of a suitable diffusion barrier layer material is silicon nitride (SiN). The device is then placed in the ampoule or reactor (not shown) and the dopants are diffused into the regions delineated by dashed lines 120A and 120B to make these areas p+ in type. The p-type dopants used for this purpose may be, for example, Zinc (Zn) atoms.

This diffusion process is referred to herein as a “deep” diffusion process due to the fact that the diffusion front, which is represented by dashed lines 130A and 130B, penetrates through the active region 111 and into the n-type diffusion accommodation layer 110. Thus, the diffusion front terminates in the diffusion accommodation layer 110. This deep diffusion process is in contrast to known “shallow” diffusion processes in which the diffusion front stops before reaching the active region. In accordance with the invention, at the locations where the diffusion front terminates in the diffusion accommodation layer 110, p+/n junctions are formed. Wherever the diffusion front did not pass through the active region 111, a continuous p/n junction exists in the active region as originally grown. The location of this p/n junction is indicated by the bracket labeled 132. As indicated above, the p+/n junctions have higher threshold voltages than that of the p/n junction, which ensures that all current will be confined to the portion of the active region 111 indicated by the bracket labeled 132.

Through this selective diffusion process, the contact regions 133 in layer 112 where the metal for the p contacts (not shown) will subsequently be placed can be selectively doped to have a higher p doping than adjacent areas in layer 112. This increase in p doping at these locations reduces series electrical resistance associated with the p metal contacts. In addition, in the area 134 in between the contact regions 133, which generally corresponds to the optical emission window, a lower p doping can be provided to reduce free carrier absorption in this area. This is particularly beneficial when the device 140 is implemented as a vertical cavity surface light emitting laser (VCSEL) having mirror structures on both sides of the active region for reflecting photons back into the active region. In such cases, the free carrier absorption loss in the emission window 134 will be reduced. In addition, in single mode laser applications, the higher p doping outside of emission window 134 can be used to suppress higher order modes that might otherwise occur due to free carrier absorption loss being so large that the higher order lasing mode is not sustainable.

With reference to FIG. 5C, after the device 140 shown in FIG. 5B has been formed, optionally, a proton implantation process may be performed to prevent or suppress current leakage. FIG. 5C illustrates a cross-sectional plan view of the device shown in FIG. 5B after a proton implantation process has been performed to produce the device 170. During this process, protons are implanted in the regions delineated by the dashed lines labeled 140A and 140B. The implantation prevents or suppresses current leakage by rendering the implanted regions semi-insulating. This is particularly useful in cases where the bandgap of the material that is used for the diffusion accommodation layer 110 is not much greater than the bandgap of the material that is used for the active layer 111.

FIG. 5D illustrates a cross-sectional view of the device 140 shown in FIG. 5B after the p contacts 162 and the n contact 163 have been added to produce the final device 200. The contacts 162 and 163 are typically metal contacts formed through a physical vapor deposition (PVD) process. The p contacts 162 are preferably located outside of the emission window to avoid light blockage and maximize light extraction. Typically, thousands of the devices 200 are simultaneously formed on a single wafer, with each device 200 corresponding to a semiconductor die. After the devices 200 have been formed, a singulation process is typically performed to separate the dies. Each die is typically then die attached to a metal leadframe (not shown) and then packaged in a protective packaging material. Prior to the dies being singulated, they may be tested on the wafer to determine whether or not they meet certain standards and/or operate satisfactorily.

It should be noted that the invention has been described with reference to a few illustrative embodiments for the purposes of demonstrating the principles and concepts of the invention. The invention, however, is not limited to these embodiments, as will be understood by persons of skill in the art in view of the disclosure provided herein. Many modifications can be made to the embodiments described herein, and all such modifications are within the scope of the invention. For example, additional layers other than those shown in FIGS. 5A-5D may be included. In the case where the semiconductor light emission device is an LED, no additional layers may be included. However, in the case where the semiconductor light emission device is a laser, such as a VCSEL, for example, additional layers may be added to form distributed Bragg reflectors (DBRs) and multi-quantum well (MQW) structures. Persons of ordinary skill in the art will understand, without having to engage in undue experimentation, the manner in which these and other modifications can be made to the devices depicted in FIGS. 5A-5D.

What is claimed is:

1. A semiconductor light emission device comprising:
a substrate of n-type material;
at least a first layer of n-type material disposed on an upper surface of the substrate;
at least one diffusion accommodation layer of n-type material disposed on said at least a first layer of n-type material;
at least one active layer of p-n material disposed on said at least one accommodation layer, said at least one active layer providing an active region in the semiconductor light emission device for conversion of electrons into photons, the material of the diffusion accommodation layer having a bandgap that is higher than a bandgap of the material of the active layer;
at least one layer of p-type material disposed on said at least one active layer;
at least one p contact disposed on said at least a first layer of p-type material;
at least one n contact disposed on a bottom surface of the substrate; and
at least first and second diffusion areas in which p dopants have been diffused into the semiconductor light emission device, the first and second diffusion areas passing through the first layer of p-type material and through the active region and terminating in the diffusion accommodation layer, wherein first and second p+/n junctions exist where the first and second diffusion areas terminate in the diffusion accommodation layer, and wherein a p/n junction exists in the active region, the existence of the first and second p+/n junctions operating as a current confinement structure by causing electrical current to be channeled away from the p+/n junctions and into the p/n junction.

2. The semiconductor light emission device of claim 1, wherein the p+/n junctions turn on at a threshold forward bias voltage that is higher than a threshold forward bias voltage at which the p/n junction turns on.

3. The semiconductor light emission device of claim 1, further comprising:
at least one proton implantation region in which protons have been implanted into the semiconductor device, the proton implantation region passing at least partially into the diffusion accommodation layer.

4. The semiconductor light emission device of claim 1, wherein the n-type material of the diffusion accommodation layer comprises aluminum arsenide (AlAs) and wherein the material of the active layer comprises gallium arsenide (GaAs).

5. The semiconductor light emission device of claim 1, wherein the n-type material of the diffusion accommodation layer comprises aluminum indium phosphide (AlInP) and wherein the material of the active layer comprises indium gallium phosphide (InGaP).

6. The semiconductor light emission device of claim 1, wherein the p dopants that are diffused into the semiconductor light emission device are zinc (Zn) atoms.

7. The semiconductor light emission device of claim 1, wherein the semiconductor light emission device is a light emitting diode (LED).

8. The semiconductor light emission device of claim 1, wherein the semiconductor light emission device is a laser diode.

9. The semiconductor light emission device of claim 8, wherein the laser diode is a vertical cavity surface emitting laser (VCSEL).

10. A method for performing current confinement in a semiconductor light emission device, the method comprising:
providing a semiconductor light emission device comprising at least an active region disposed between first and second layers, the active region comprising at least one layer of p-n material, the first layer comprising at least one diffusion accommodation layer of n-type material, the second layer comprising at least one layer of p-type material, wherein the material of the diffusion accommodation layer has a bandgap that is higher than a bandgap of the material of the active region;
forming a first diffusion area in the semiconductor light emission device by diffusing p dopants into the semiconductor light emission device, the first diffusion area passing through the first layer and the active region and terminating in the diffusion accommodation layer, wherein a first p+/n junction exists where the first diffusion area terminates in the diffusion accommodation layer; and
forming a second diffusion area in the semiconductor light emission device by diffusing p dopants into the semiconductor light emission device, the second diffusion area passing through the first layer and the active region and terminating in the diffusion accommodation layer, wherein a second p+/n junction exists where the second diffusion area terminates in the diffusion accommodation layer, and wherein a p/n junction exists in the active region, the existence of the first and second p+/n junctions operating as a current confinement structure by causing electrical current to be channeled away from the p+/n junctions and into the p/n junction.

11. The method of claim 10, wherein the p+/n junctions turn on at a threshold forward bias voltage that is higher than a threshold forward bias voltage at which the p/n junction turns on.

12. The method of claim 10, further comprising:
forming at least one proton implantation region in the semiconductor light emission device by implanting protons such that the proton implantation region passes at least partially into the diffusion accommodation layer.

13. The method of claim 10, wherein the n-type material of the diffusion accommodation layer comprises aluminum arsenide (AlAs) and wherein the material of the active layer comprises gallium arsenide (GaAs).

14. The method of claim 10, wherein the n-type material of the diffusion accommodation layer comprises aluminum indium phosphide (AlInP) and wherein the material of the active layer comprises indium gallium phosphide (InGaP).

15. The method of claim 10, wherein the p dopants that are diffused into the semiconductor light emission device are zinc (Zn) atoms.

16. The method of claim 10, wherein the semiconductor light emission device includes a substrate of n-type material and a third layer of n-type material disposed on an upper surface of the substrate, the diffusion accommodation layer being disposed on the third layer of n-type material.

17. The method of claim 16, wherein the semiconductor light emission device includes a p contact disposed on the second layer and an n contact disposed on a bottom surface of the substrate.
